(19) United States
(12) Patent Application Publication
(10) Pub. No.: US 2023/0389248 A1
(43) Pub. Date: Nov. 30, 2023

(54) COMPONENT MOUNTING DEVICE

(71) Applicant: FUJI CORPORATION, Chiryu (JP)

(72) Inventors: Mikako KAWASAKI, Chiryu-shi (JP); Ryosuke MORI, Kitanagoya-shi (JP)

(73) Assignee: FUJI CORPORATION, Chiryu (JP)

(21) Appl. No.: 18/325,168

(22) Filed: May 30, 2023

(30) Foreign Application Priority Data
May 30, 2022 (JP) 2022-087649

(51) Int. Cl. H05K 13/04; B65G 47/91

(52) U.S. Cl. CPC H05K 13/0409; B65G 47/91

(57) ABSTRACT

It is possible to appropriately determine whether a component is picked up when a nozzle having a small diameter is used. A component mounting device to which multiple types of nozzles having different sizes of suction ports each configured to pick up a component are detachably attached, includes: a nozzle flow path configured to supply a negative pressure from a negative pressure source to the suction port of the nozzle; a pressure sensor configured to detect a pressure in the nozzle flow path; a determining section configured to determine whether the component is picked up based on a detected value of the pressure sensor; and a flow rate changing section configured to change a flow rate of the negative pressure supplied from the nozzle flow path to the suction port in accordance with a size of the suction port.

### TECHNICAL FIELD

The present specification discloses a component mounting device.

### BACKGROUND ART

Conventionally, as a component mounting device, in a device that mounts a component picked up at a suction port of a nozzle through a negative pressure on a substrate, a device that detects a connection state of an air path, whether component is picked up, or the like has been proposed. For example, in a device of Patent Literature 1, an air state detecting device that detects an air pressure in a path is provided on an air supply path, and whether a detected value of the air state detecting device is a predetermined threshold value or less is determined, determination is made that connection of the air path is defective in a case where the detected value is not the predetermined threshold value or less, and determination is made that the connection is good in a case where the detected value is the predetermined threshold value or less.

### PATENT LITERATURE

Patent Literature 1: International Publication WO 2017/203626

### SUMMARY OF THE INVENTION

### Technical Problem

As in the component mounting device described above, it is conceivable to determine whether the component is picked up based on the detected value of the air state detecting device. However, in a case where a nozzle of which a suction port has a relatively small diameter is used, a pressure difference between a pressure in normal pickup and a pressure in leak may decrease as compared with a case where a nozzle having a relatively large diameter is used, and a pressure difference may rarely occur. Therefore, it is difficult to appropriately determine whether the component is picked up based on the detected value of the pressure.

A main object of the present disclosure is to enable an appropriate determination as to whether a component is picked up when a nozzle having a small diameter is used.

### Solution to Problem

The present disclosure employs the following means in order to achieve the above-described main object.

The gist of the component mounting device of the present disclosure relates to a component mounting device to which multiple types of nozzles having different sizes of suction ports each configured to pick up a component are detachably attached, the component mounting device including: a nozzle flow path configured to supply a negative pressure from a negative pressure source to the suction port of the nozzle; a pressure sensor configured to detect a pressure in the nozzle flow path; a determining section configured to determine whether the component is picked up based on a detected value of the pressure sensor; and a flow rate changing section configured to change a flow rate of the negative pressure supplied from the nozzle flow path to the suction port in accordance with a size of the suction port.

The component mounting device of the present disclosure changes the flow rate of the negative pressure supplied from the nozzle flow path to the suction port in accordance with the size of the suction port. With this, in a case where a component is picked up by a nozzle having a relatively small diameter, the flow rate of the negative pressure is reduced, so that a pressure difference between a pressure in normal pickup and a pressure in leak can be made apparent. Accordingly, when a nozzle having a small diameter is used, it is possible to appropriately determine whether the component is picked up.

### BRIEF DESCRIPTION OF DRAWINGS

FIG. 1 is a perspective view schematically showing a configuration of component mounting device 10.

FIG. 2 is a block diagram showing an electrical connection relationship of component mounting device 10.

FIG. 3 is a block diagram showing a principal configuration for supplying pressure.

FIG. 4 is a configuration diagram schematically showing a configuration of pressure supply device 70.

FIG. 5 is an explanatory diagram of a case where a negative pressure is supplied to suction port 52a when nozzle holding section 51 holds large-diameter nozzle 52L as a nozzle for picking up a component.

FIG. 6 is an explanatory diagram of a case where a negative pressure is supplied to suction port 52a when nozzle holding section 51 holds small-diameter nozzle 52S as the nozzle for picking up a component.

FIG. 7 is an explanatory diagram showing a state of a change in the negative pressure in component pickup and in air leak.

### DESCRIPTION OF EMBODIMENTS

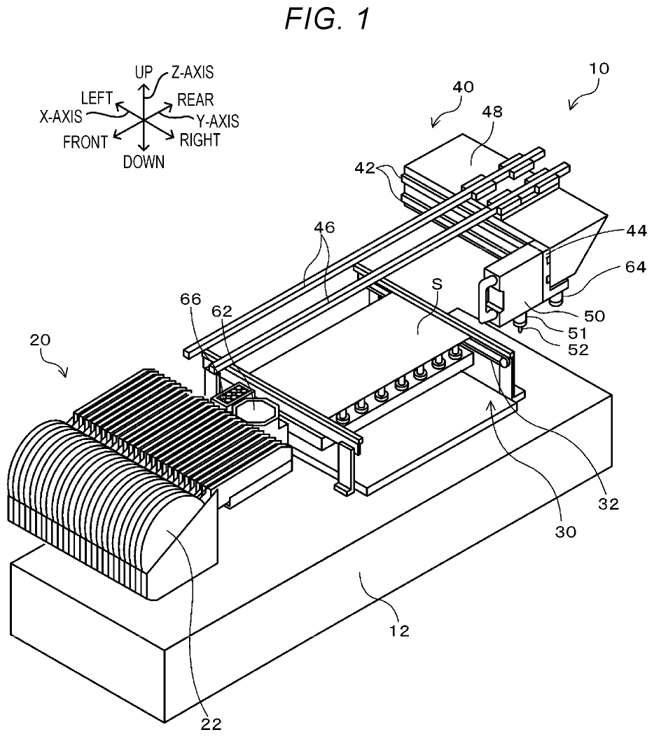

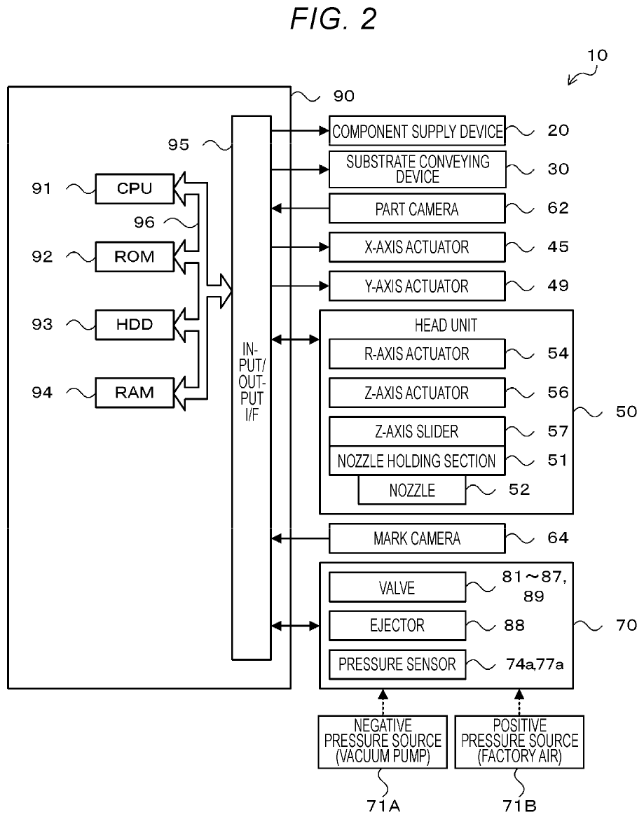

Next, an embodiment of the present disclosure will be described with reference to the drawings. FIG. 1 is a perspective view schematically showing a configuration of component mounting device 10. FIG. 2 is a block diagram showing an electrical connection relationship of component mounting device 10. In the present embodiment, a left-right direction in FIG. 1 is an X-axis direction, a front-rear direction is a Y-axis direction, and an up-down direction is a Z-axis direction.

As shown in FIG. 1, component mounting device 10 includes component supply device 20, substrate conveying device 30, moving device 40, head unit 50, part camera 62, mark camera 64, nozzle stocker 66, pressure supply device 70 (see FIG. 2), and control device 90 (see FIG. 2). Component supply device 20 is provided on a front portion of base 12 of component mounting device 10, is, for example, a tape feeder including reel 22 in which components are accommodated in a tape at predetermined intervals, and pulls out the tape from reel 22 through the drive of a motor (not shown) to supply the components to a supply position. Substrate conveying device 30 includes, for example, a pair of conveyor belts 32 provided on base 12 to be spaced apart from each other in the front-rear direction (Y-axis direction) and spanned in the left-right direction, and conveys substrate S from the left to the right in FIG. 1 by driving conveyor belts 32 through the drive of a motor (not shown). Moving device 40 includes guide rail 46 provided along the Y-axis direction, Y-axis slider 48 moving along guide rail 46, guide rail 42 provided on Y-axis slider 48 along the X-axis direction, and X-axis slider 44 moving along guide rail 42. Head unit 50 is attached to X-axis slider 44. Moving device 40 moves head unit 50 in the XY direction by moving X-axis slider 44 and Y-axis slider 48.

Head unit 50 is configured as, for example, a single nozzle head in which one nozzle 52 is attached onto an axial center line, and includes R-axis actuator 54 and Z-axis actuator 56 (see FIG. 2). Head unit 50 rotates nozzle 52 around the axial center line of head unit 50 through the drive of R-axis actuator 54. In addition, head unit 50 raises and lowers Z-axis slider 57 (see FIG. 2) in the Z-axis direction through the drive of Z-axis actuator 56. Nozzle holding section 51 (see FIG. 2) that holds nozzle 52 is provided at a lower end of Z-axis slider 57, and Z-axis slider 57 raises and lowers nozzle 52 in the Z-axis direction through the drive of Z-axis actuator 56. Nozzle 52 picks up a component at a nozzle tip using a negative pressure, or releases the component from the pickup using a positive pressure. Nozzle 52 is held at nozzle holding section 51 by a negative pressure. Pressure supply device 70 supplies a negative pressure and a positive pressure to nozzle holding section 51 and nozzle 52, and the details thereof will be described below.

Part camera 62 is provided between component supply device 20 and substrate conveying device 30. An imaging range is above part camera 62, and part camera 62 images a target object, such as a component picked up by nozzle 52, from below to generate a captured image.

Mark camera 64 is provided on a lower surface of X-axis slider 44. Mark camera 64 images a target object from above to generate a captured image. Examples of the target object of mark camera 64 include a component supplied from the tape feeder of component supply device 20, a mark affixed to substrate S, and a mark of nozzle 52 in nozzle stocker 66.

Nozzle stocker 66 is configured to accommodate multiple types of nozzles 52 having different sizes and shapes in respective accommodating sections. Nozzles 52 with which nozzle stocker 66 is stocked can be automatically exchanged for head unit 50. In addition, during the stop of the operation of component mounting device 10, the operator can take out a type of nozzle 52 unnecessary for a mounting process from among nozzles 52 with which nozzle stocker 66 is stocked, and cause nozzle stocker 66 to accommodate a type of nozzle 52 necessary for the mounting process.

As shown in FIG. 2, control device 90 is configured as a microprocessor centered on CPU 91 and includes ROM 92, HDD 93, RAM 94, input/output interface (I/F) 95, and the like in addition to CPU 91. These are connected via bus 96. Control device 90 causes component mounting device 10 to perform component mounting process based on a production job of substrate S acquired from a management device (not shown) or the like. The production job is data defining which components are mounted on substrate S in which order in component mounting device 10, how many substrates S on which the components are mounted in such a manner are to be manufactured, and the like. In addition, control device 90 automatically exchanges nozzle 52 attached to head unit 50 with nozzle 52 having a size (diameter) or a shape suitable for mounting components, and acquires information on the size or the shape of attached nozzle 52.

In addition, control device 90 inputs image signals and the like from part camera 62 and mark camera 64 via input/output interface 95. X-axis slider 44, Y-axis slider 48, and Z-axis slider 57 are each provided with a position sensor (not shown), and control device 90 also inputs position information from those position sensors. In addition, control device 90 outputs drive signals and the like to component supply device 20, substrate conveying device 30, X-axis actuator 45 that moves X-axis slider 44, Y-axis actuator 49 that moves Y-axis slider 48, Z-axis actuator 56 that moves Z-axis slider 57, and pressure supply device 70, via input/output interface 95.

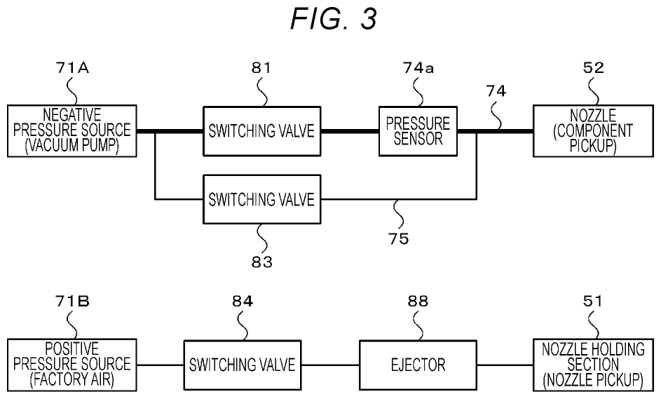

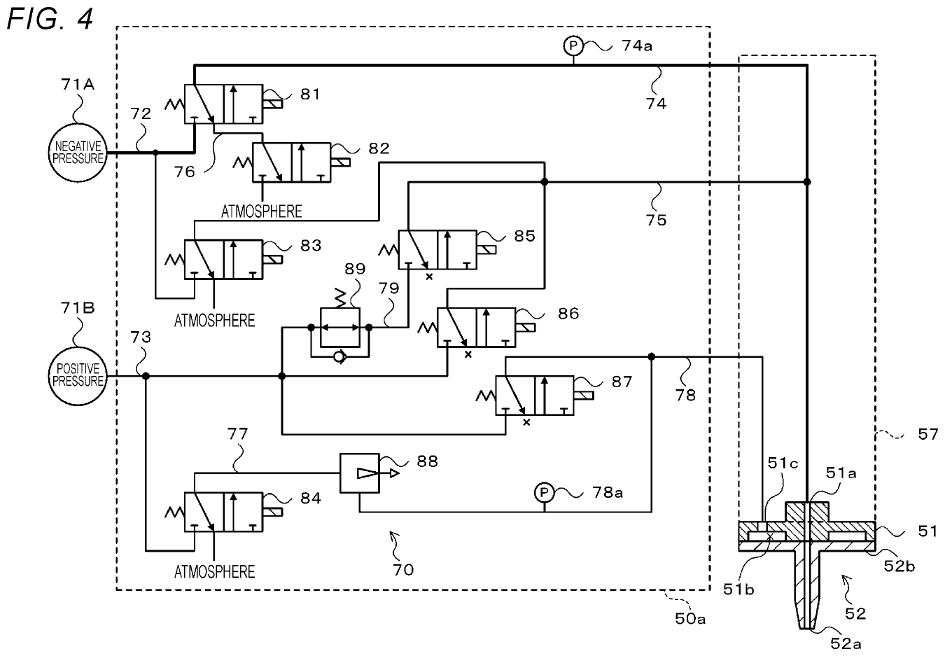

Hereinafter, pressure supply device 70 for supplying a negative pressure or a positive pressure to nozzle holding section 51 or nozzle 52 will be described. FIG. 3 is a block diagram showing a principal configuration for supplying pressure. FIG. 4 is a configuration diagram schematically showing a configuration of pressure supply device 70. In the present embodiment, as shown in FIG. 3, the negative pressure from the vacuum pump serving as negative pressure source 71A is configured to be supplied to nozzle 52 from a flow path with a relatively large flow rate (large flow rate flow path 74) via switching valve 81 and to be supplied to nozzle 52 from a flow path with a relatively small flow rate (small flow rate flow path 75) via switching valve 83. At least one of a negative pressure of a large flow rate and a negative pressure of a small flow rate is supplied to nozzle 52, whereby nozzle 52 is configured to pick up the component. The vacuum pump serving as negative pressure source 71A is provided in component mounting device 10. In addition, a positive pressure from a factory air serving as positive pressure source 71B is supplied to ejector 88 via switching valve 84, and a negative pressure generated by ejector 88 using the positive pressure is supplied to nozzle holding section 51, whereby nozzle holding section 51 is configured to pick up nozzle 52.

Here, as shown in FIG. 4, nozzle 52 picks up a component at suction port 52a provided at a tip (lower end) of a shaft portion having a tubular shape, and flange portion 52b is formed so as to protrude in a radial direction from an upper end of the shaft portion. In addition, nozzle holding section 51 is formed with center hole 51a provided at a lower end of Z-axis slider 57 and vertically penetrating a center portion, annular recessed portion 51b provided in a lower surface (holding surface) on which nozzle 52 is held, and communication hole 51c penetrating vertically so as to communicate from an upper surface to a bottom surface of recessed portion 51b. Recessed portion 51b of nozzle holding section 51 is covered with an upper surface of flange portion 52b of attached nozzle 52, thereby forming a negative pressure chamber. A negative pressure is supplied to the negative pressure chamber (into recessed portion 51b) via communication hole 51c, whereby nozzle holding section 51 can pick up and hold nozzle 52. In addition, a negative pressure is supplied to suction port 52a via center hole 51a of nozzle holding section 51 and the center hole of the shaft portion, whereby nozzle 52 can pick up and hold a component at suction port 52a. Although not shown, a permanent magnet is embedded in a part of the bottom surface of recessed portion 51b. In addition, a metal plate is embedded in a position of the upper surface (a held surface) of flange portion 52b of nozzle 52 facing the permanent magnet of recessed portion 51b. Therefore, nozzle 52 is held at nozzle holding section 51 by the suction force of the negative pressure and the suction force of the magnet.

Pressure supply device 70 includes multiple flow paths through which air of a positive pressure or a negative pressure flows, multiple switching valves 81 to 87 that switch the communication state of each flow path, ejector 88, and pressure reducing valve 89. Pressure supply device 70 includes, as main flow paths, negative pressure flow path 72, positive pressure flow path 73, large flow rate flow path 74, small flow rate flow path 75, connection flow path 76, ejector flow path 77, nozzle holding flow path 78, and reduced pressure flow path 79. In addition, pressure supply device 70 includes pressure sensor 74a that detects the pressure (negative pressure) in large flow rate flow path 74 and small flow rate flow path 75, and pressure sensor 78a that detects the pressure (negative pressure) in nozzle holding flow path 78, and outputs the detected pressure to control device 90. In the present embodiment, pressure supply device 70 (multiple switching valves 81 to 87, ejector 88, and pressure reducing valve 89) is provided inside head main body 50a of head unit 50, and each is operated based on a drive signal from control device 90. Further, a part of the flow path, for example, a part of large flow rate flow path 74, small flow rate flow path and nozzle holding flow path 78 is configured to supply pressure to nozzle holding section 51 and nozzle 52 through Z-axis slider 57.

Negative pressure flow path 72 is a flow path communicating with negative pressure source 71A. Positive pressure flow path 73 is a flow path communicating with positive pressure source 71B. Large flow rate flow path 74 is a flow path communicating with center hole 51a of nozzle holding section 51 and supplying a negative pressure of a large flow rate to suction port 52a of nozzle 52 via center hole 51a. Small flow rate flow path 75 is a flow path communicating with large flow rate flow path 74 (center hole 51a of nozzle holding section 51) and supplying a negative pressure of a smaller flow rate than large flow rate flow path 74 to suction port 52a of nozzle 52. Large flow rate flow path 74 and small flow rate flow path 75 function as a negative pressure supply flow path for component pickup for supplying a negative pressure that is used for nozzle 52 to pick up the component. Small flow rate flow path 75 is configured as a flow path having a smaller diameter than large flow rate flow path 74 and has an inner diameter of, for example, about ⅓ to ½ of large flow rate flow path 74. Ejector flow path 77 is a flow path supplying a positive pressure to be caused to flow through ejector 88. Nozzle holding flow path 78 is a flow path communicating with communication hole 51c of nozzle holding section 51 and supplying the negative pressure generated by ejector 88 into recessed portion 51b via communication hole 51c. That is, nozzle holding section 51 functions as a negative pressure supply flow path for nozzle holding for supplying a negative pressure for holding (picking up) nozzle 52. Reduced pressure flow path 79 is a flow path through which air obtained by reducing the positive pressure of positive pressure flow path 73 by pressure reducing valve 89 flows.

Switching valve 81 switches between a state in which negative pressure flow path 72 and large flow rate flow path 74 communicate with each other and large flow rate flow path 74 and connection flow path 76 are shut off from each other and a state in which negative pressure flow path 72 and large flow rate flow path 74 are shut off from each other and large flow rate flow path 74 and connection flow path 76 communicate with each other. Switching valve 81 switches to a state in which negative pressure flow path 72 and large flow rate flow path 74 communicate with each other to supply the negative pressure from negative pressure source 71A to large flow rate flow path 74, whereby the negative pressure can be supplied to suction port 52a of nozzle 52. Switching valve 82 switches between a state in which connection flow path 76 is opened to the atmosphere and a state in which connection flow path 76 is shut off from the atmosphere. Switching valve 81 switches to a state in which large flow rate flow path 74 and connection flow path 76 communicate with each other and switching valve 82 switches to a state in which connection flow path 76 is opened to the atmosphere to supply the atmospheric pressure to large flow rate flow path 74, whereby the atmospheric pressure can be supplied to suction port 52a of nozzle 52.

Switching valve 83 switches between a state in which negative pressure flow path 72 and small flow rate flow path 75 communicate with each other and a state in which negative pressure flow path 72 and small flow rate flow path 75 are shut off from each other. Switching valve 83 switches to a state in which negative pressure flow path 72 and small flow rate flow path communicate with each other to supply the negative pressure from negative pressure source 71A to small flow rate flow path 75, whereby the negative pressure can be supplied to suction port 52a of nozzle 52. As will be described below, small flow rate flow path 75 is connected to switching valves 85 and 86. Therefore, in order to supply the negative pressure to nozzle 52 through small flow rate flow path 75, it is necessary for switching valves 85 and 86 to switch to a state in which connection between small flow rate flow path 75 and the other flow paths is shut off from each other.

Switching valve 84 switches between a state in which ejector flow path 77 communicates with positive pressure flow path 73 and a state in which ejector flow path 77 is opened to the atmosphere. Ejector 88 operates such that air of the positive pressure supplied from ejector flow path 77 flows at a high speed, thereby sucking the air in nozzle holding flow path 78. As a result, by supplying the negative pressure to nozzle holding flow path 78, the negative pressure can be supplied into recessed portion 51b via communication hole 51c of nozzle holding section 51.

Switching valve 85 switches between a state in which reduced pressure flow path 79 and small flow rate flow path 75 communicate with each other and a state in which reduced pressure flow path 79 and small flow rate flow path 75 are shut off from each other. Switching valve 86 switches between a state in which positive pressure flow path 73 and small flow rate flow path 75 communicate with each other and a state in which positive pressure flow path 73 and small flow rate flow path 75 are shut off from each other. As described above, in a case where switching valve 83 switches to a state in which negative pressure flow path 72 and small flow rate flow path communicate with each other, switching valve 85 switches to a state in which reduced pressure flow path 79 and small flow rate flow path 75 are shut off from each other, and switching valve 86 switches to a state in which positive pressure flow path 73 and small flow rate flow path 75 are shut off from each other. Switching valve 83 switches to a state in which negative pressure flow path 72 and small flow rate flow path 75 are shut off from each other, switching valve 85 switches to a state in which reduced pressure flow path 79 and small flow rate flow path 75 communicate with each other, and switching valve 86 switches to a state in which positive pressure flow path 73 and small flow rate flow path 75 are shut off from each other, whereby the reduced positive pressure is supplied from small flow rate flow path 75 to suction port 52a of nozzle 52. As a result, by releasing the component that has been picked up by nozzle 52 from the pickup, the component can be mounted on substrate S. In addition, switching valve 83 switches to a state in which negative pressure flow path 72 and small flow rate flow path 75 are shut off from each other, switching valve 85 switches to a state in which reduced pressure flow path 79 and small flow rate flow path are shut off from each other, and switching valve 86 switches to a state in which positive pressure flow path 73 and small flow rate flow path 75 communicate with each other, whereby the positive pressure of positive pressure source 71B can be supplied from small flow rate flow path to suction port 52a of nozzle 52. As a result, by supplying a relatively high positive pressure to nozzle 52, it is possible to remove clogging or the like of nozzle 52.

Switching valve 87 switches between a state in which positive pressure flow path 73 and nozzle holding flow path 78 communicate with each other and a state in which positive pressure flow path 73 and nozzle holding flow path 78 are shut off from each other. Switching valve 87 switches to a state in which positive pressure flow path 73 and nozzle holding flow path 78 communicate with each other to supply a positive pressure to nozzle holding flow path 78, whereby the positive pressure can be supplied into recessed portion 51b via communication hole 51c of nozzle holding section 51. As a result, nozzle 52 that has been picked up by nozzle holding section 51 can be released from the pickup.

In pressure supply device 70 of the present embodiment configured as described above, the negative pressure generated by ejector 88 using the positive pressure passing from positive pressure source 71B through positive pressure flow path 73 is supplied from nozzle holding flow path 78 to nozzle holding section 51 to hold nozzle 52. In addition, pressure supply device 70 supplies the negative pressure generated by negative pressure source 71A (negative pressure pump) to nozzle 52 from at least one of large flow rate flow path 74 and small flow rate flow path 75 through negative pressure flow path 72 to hold a component. Here, in a case where the component is picked up by nozzle 52, air leak need not be a problem as long as suction port 52a and the component are in close contact with each other. However, actually, in a case where it is difficult for suction port 52a to come into close contact with the component because of the shape of the component and the state of the upper surface, air leak is likely to occur. For example, in a component of which an upper surface has a hemispherical shape, such as an LED component, leak is likely to occur because a gap with a spherical surface increases depending on the pickup position. In addition, in a component including an operation section provided on an upper surface, such as a switch component, in a case where suction port 52a touches a level difference portion between the operation section and the periphery thereof, leak is likely to occur. In a case where the generation source and the supply flow path of the negative pressure used for the pickup of nozzle 52 and the pickup of the component are shared, the air leak caused by the pickup of the component may affect the pickup of nozzle 52 to decrease the pickup force (holding force), and nozzle 52 may fall. In pressure supply device 70 of the present embodiment, since the generation source and the supply flow path of the negative pressure used for the pickup of nozzle 52 and the pickup of the component are separately configured, it is possible to prevent the leak from affecting the pickup of nozzle 52.

In addition, as described above, in picking up (holding) the component, there is a probability of air leak depending on the component type, and a stable supply of the negative pressure is required in order to appropriately hold the component while allowing leak. Here, although ejector 88 is generally more compact in configuration and less expensive than the vacuum pump, the stability of the generated negative pressure is higher in the vacuum pump. Therefore, in order for ejector 88 to supply a necessary negative pressure flow rate equivalent to the vacuum pump, ejector 88 having a large body size is necessary, and mounting on head unit 50 (head main body 50a) is difficult. In addition, since the positive pressure flow rate supplied to ejector 88 increases, the consumption flow rate of component mounting device 10 may increase. In that respect, in pressure supply device 70 of the present embodiment, by using the negative pressure from the vacuum pump for the pickup of the component, the pickup of the component can be stably performed while preventing those problems from occurring. Therefore, even in a component in which leak is likely to occur, it is possible to stabilize the posture of the component during pickup and to appropriately mount the component.

Meanwhile, in holding nozzle 52 relative to the holding of the component, since the negative pressure chamber formed by nozzle holding section 51 (recessed portion 51b) of head unit 50 and the upper surface of flange portion 52b of nozzle 52 is in a sealed state, the leak rarely occurs. Therefore, nozzle 52 can be held at a small flow rate, so that a smaller ejector can be selected than in a case where ejector 88 is used for holding a component. In pressure supply device 70 of the present embodiment, since the negative pressure generated by ejector 88 is used for the pickup (holding) of nozzle 52, it is possible to make the device more compact and reduce the cost as compared with a case where vacuum pumps are provided for the pickup of the component and the pickup of nozzle 52, respectively. Further, since ejector 88 is provided in head main body 50a of head unit 50, it is possible to prevent an increase in length of nozzle holding flow path 78 as compared with a configuration in which ejector 88 is provided outside head main body 50a, for example, on base 12 of component mounting device 10, or the like. Therefore, since the negative pressure can be appropriately applied from ejector 88 to nozzle holding section 51 via nozzle holding flow path 78, the pickup of nozzle 52 can be stabilized. The suction force of the magnet is also used for the pickup of nozzle 52 (flange portion 52b). In these respects, even with the negative pressure generated by ejector 88, no problem may occur in picking up nozzle 52.

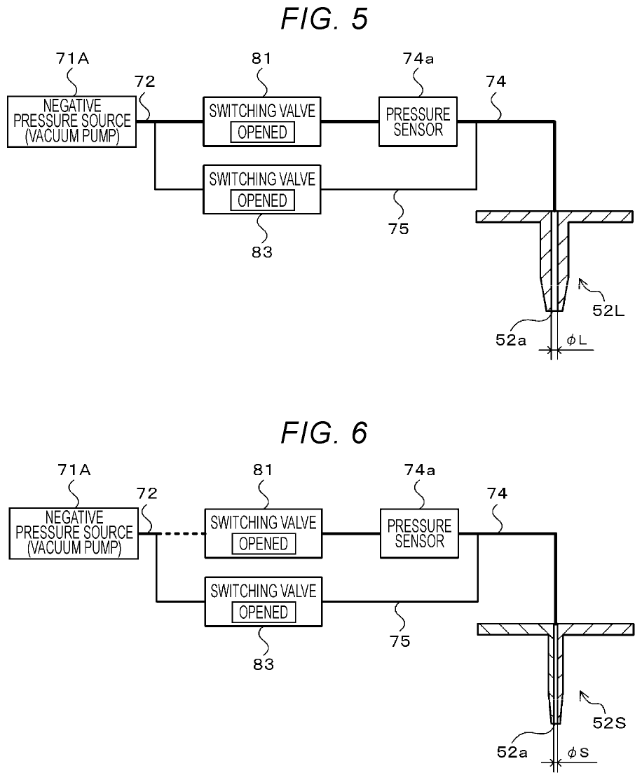

Further, pressure supply device 70 has two flow paths, that is, large flow rate flow path 74 and small flow rate flow path 75, as a negative pressure supply flow path for component pickup. Here, FIG. 5 is an explanatory diagram of a case where a negative pressure is supplied to suction port 52a when nozzle holding section 51 holds large-diameter nozzle 52L as the nozzle for picking up a component. Here, 9L, which is the size (opening diameter) of suction port 52a of large-diameter nozzle 52L, is larger than a predetermined size (predetermined diameter). FIG. 6 is an explanatory diagram of a case where a negative pressure is supplied to suction port 52a when nozzle holding section 51 holds small-diameter nozzle 52S as the nozzle for picking up a component. Here, 9S, which is the size (opening diameter) of suction port 52a of small-diameter nozzle 52S, is smaller than the predetermined size (predetermined diameter). As shown in FIG. 5, in a case where a component is picked up by large-diameter nozzle 52L, control device 90 causes switching valve 81 to switch to a state (opened state) in which negative pressure flow path 72 and large flow rate flow path 74 communicate with each other, and causes switching valve 83 to switch to a state (opened state) in which negative pressure flow path 72 and small flow rate flow path 75 communicate with each other. As a result, the negative pressure can be supplied to large-diameter nozzle 52L from the two supply flow paths, that is, large flow rate flow path 74 and small flow rate flow path 75. Therefore, as compared with a case where the negative pressure is supplied from only large flow rate flow path 74, a negative pressure of a larger flow rate (maximum flow rate) can be supplied to large-diameter nozzle 52L. In addition, in a case where a component is picked up by small-diameter nozzle 52S, control device 90 causes switching valve 81 to switch to a state (closed state) in which negative pressure flow path 72 and large flow rate flow path 74 are shut off from each other and large flow rate flow path 74 and connection flow path 76 communicate with each other, and causes switching valve 83 to switch to a state (opened state) in which negative pressure flow path 72 and small flow rate flow path 75 communicate with each other. Switching valve 82 switches to a state in which connection flow path 76 is shut off from the atmosphere. As a result, a negative pressure of a small flow rate can be supplied from small flow rate flow path 75 to small-diameter nozzle 52S.

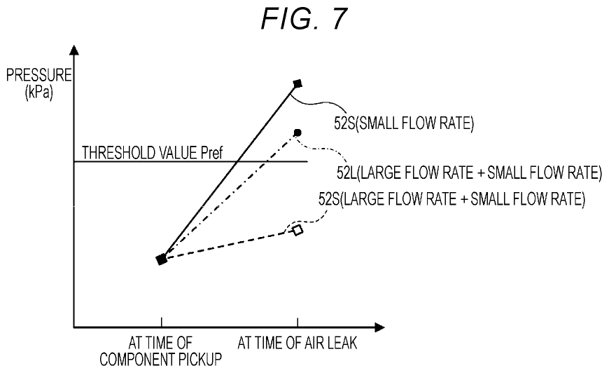

Here, FIG. 7 is an explanatory diagram showing a state of a change in the negative pressure in component pickup and in air leak. In FIG. 7, the vertical axis represents the negative pressure, and the horizontal axis represents the time of component pickup (no air leak) and the time of air leak, and it is assumed that the negative pressure increases to the negative side to be below threshold value Pref in a case where a component is normally pickup by nozzle 52, and the negative pressure is above threshold value Pref in a case where the air leak has occurred. As shown in the drawing, in a case where a negative pressure of “a large flow rate+a small flow rate” is supplied from large flow rate flow path 74 and small flow rate flow path 75 to large-diameter nozzle 52L (alternate long and short dash line), the negative pressure is above threshold value Pref in air leak. Therefore, control device 90 can determine the abnormality of the pickup based on the detected value of pressure sensor 74a. In other words, since the change in the pressure (negative pressure) in air leak is large, whether the component is picked up can be appropriately detected. On the other hand, unlike the present embodiment, in a case where a negative pressure of “a large flow rate+a small flow rate” is supplied from large flow rate flow path 74 and small flow rate flow path 75 to small-diameter nozzle 52S (dashed line), the negative pressure remains below threshold value Pref in air leak. Therefore, control device 90 cannot determine the abnormality of the pickup based on the detected value of pressure sensor 74a. In other words, since the pressure change in air leak is small, whether the component is picked up cannot be appropriately detected. In that respect, in the present embodiment, since the negative pressure of “a small flow rate” is supplied from small flow rate flow path 75 to small-diameter nozzle 52S (solid line), the negative pressure is above threshold value Pref in air leak. As a result, control device 90 can determine the abnormality of the pickup based on the detected value of pressure sensor 74a. In other words, by increasing the pressure change in air leak, whether the component is picked up can be appropriately detected. In a case where large-diameter nozzle 52L is used, the negative pressure is supplied from the two supply flow paths, that is, large flow rate flow path 74 and small flow rate flow path 75, to quickly reach the necessary negative pressure, so that the pickup of the component can be performed reliably and quickly.

Here, a correspondence relationship between elements of the present embodiment and elements of the present disclosure will be clarified. Large flow rate flow path 74 and small flow rate flow path 75 of the present embodiment correspond to the nozzle flow path of the present disclosure, pressure sensor 74a corresponds to the pressure sensor, control device 90 corresponds to the determining section, and switching valves 81 and 83 and control device 90 correspond to the flow rate changing section. In addition, large flow rate flow path 74 corresponds to a first flow path, and small flow rate flow path 75 corresponds to a second flow path.

In component mounting device 10 of the embodiment described above, in a case where a component is picked up by small-diameter nozzle 52S of which suction port 52a has a size less than a predetermined size (predetermined diameter), a negative pressure of a smaller flow rate is supplied to suction port 52a than in a case where a component is picked up by large-diameter nozzle 52L of which suction port 52a has a size equal to or more than the predetermined size. As a result, in a case where a component is picked up by small-diameter nozzle 52S, since the flow rate of the negative pressure is reduced so that the pressure difference between the pressure in the normal pickup and the pressure in the leak can be made apparent, it is possible to appropriately detect whether the component is picked up when small-diameter nozzle 52S is used.

In addition, large flow rate flow path 74 and small flow rate flow path 75 are provided as a negative pressure supply flow path (nozzle flow path) for component pickup, and the flow rate of the negative pressure supplied to nozzle 52 is changed by switching between the presence and absence of the negative pressure supply (negative pressure supply state) of large flow rate flow path 74 and small flow rate flow path 75 with switching valves 81 and 83. Therefore, the configuration in which whether a component is picked up when small-diameter nozzle 52S is used can be appropriately detected can be made relatively simple.

In addition, in a case where a component is picked up by large-diameter nozzle 52L, since the negative pressure is supplied from both large flow rate flow path 74 and small flow rate flow path 75, a negative pressure of a large flow rate can quickly reach the necessary negative pressure even in a case where the flow path is divided into two flow paths in order to appropriately detect whether the component is picked up. Therefore, the pickup of the component can be quickly and stably performed by large-diameter nozzle 52L.

As a matter of course, the present disclosure is not limited to the above-described embodiment in any way and can be implemented in various aspects without departing from the technical scope of the present disclosure.

For example, in the above-described embodiment, in a case where a component is picked up by nozzle 52 having a predetermined size or more, the negative pressure is supplied from both the flow paths, that is, large flow rate flow path 74 and small flow rate flow path 75; however, the configuration is not limited to this, and the negative pressure may be supplied from only large flow rate flow path 74.

In the above-described embodiment, large flow rate flow path 74 and small flow rate flow path 75 are provided, and the flow rate of the negative pressure is changed in two stages by switching between the presence and absence of the negative pressure supply of large flow rate flow path 74 and small flow rate flow path 75; however, the configuration is not limited to this, and the flow rate of the negative pressure may be changeable in three or more stages depending on the size of suction port 52a of nozzle 52. In this case, multiple flow paths for supplying the same flow rate may be provided to change the flow rate of the negative pressure supplied to suction port 52a of nozzle 52 in accordance with the number of switching valves to be opened. In addition, the flow rate of the negative pressure may be changed by changing the driving state of the vacuum pump, for example, the rotation speed of the vacuum pump serving as negative pressure source 71A. That is, control device 90 may drive the vacuum pump at a low rotation to supply a negative pressure of a small flow rate in a case where a component is picked up by small-diameter nozzle 52S, and drive the vacuum pump at a high rotation to supply a negative pressure of a large flow rate in a case where a component is picked up by large-diameter nozzle 52L. Alternatively, control device 90 may continuously change the flow rate of the negative pressure by continuously changing the rotation speed of the vacuum pump in accordance with the size of suction port 52a of nozzle 52. Even with such a configuration, similarly to the embodiment, it is possible to appropriately detect whether a component is picked up when a nozzle having a small diameter is used. In addition, in a case where the flow rate of the negative pressure is changed by changing the driving state of the vacuum pump, a configuration may be employed in which a single flow path is provided as the negative pressure supply flow path (nozzle flow path) for component pickup.

In the embodiment, the positive pressure from positive pressure flow path 73 is shared for the pickup release of the component, the pickup release of nozzle 52, and the generation of the negative pressure by ejector 88; however, the configuration is not limited to this. Flow paths for separately supplying the positive pressure used for the pickup release of the component or the pickup release of nozzle 52, and the positive pressure used for the generation of a negative pressure by ejector 88 may be provided, respectively.

In the embodiment, head unit 50 includes (accommodates) pressure supply device 70; however, the configuration is not limited to this, and a part of the configuration of pressure supply device 70 (a part of switching valves 81 to 87, ejector 88, and pressure reducing valve 89) may be accommodated in X-axis slider 44, Y-axis slider 48, base 12 of component mounting device 10, or the like. However, in order for ejector 88 to more reliably apply the negative pressure, it is preferable to employ the configuration described in the embodiment.

In the embodiment, the negative pressure generated by ejector 88 using the positive pressure from positive pressure flow path 73 is used for the pickup of nozzle 52; however, the configuration is not limited to this, and the negative pressure generated by the vacuum pump may be used for the pickup of nozzle 52. In order to prevent the influence of leak in component pickup, it is preferable to provide a vacuum pump for nozzle pickup separately from the component pickup.

In the embodiment, component mounting device 10 includes one vacuum pump as negative pressure source 71A; however, the configuration is not limited to this, and two vacuum pumps may be provided. For example, negative pressure source 71A may include two pumps, that is, a negative pressure pump connected to negative pressure flow path 72 to switching valve 81 and a negative pressure pump connected to the negative pressure flow path to switching valve 83. In such a case, negative pressure flow path 72 to switching valve 81 and the negative pressure flow path to switching valve 83 may be connected to each other or may be independent of each other.

Here, the component mounting device of the present disclosure may be configured as follows. For example, in the component mounting device of the present disclosure, the nozzle flow path may include a first flow path and a second flow path having a smaller flow path diameter than the first flow path, and the flow rate changing section may change to supply a negative pressure of a large flow rate from at least the first flow path in a case where the size of the suction port is a predetermined size or more, and change to shut off supply of the negative pressure from the first flow path and to supply a negative pressure of a small flow rate from the second flow path in a case where the size of the suction port is less than the predetermined size. With this, a configuration in which whether a component is picked up when a nozzle having a small diameter is used can be appropriately detected can be made relatively simple.

In the component mounting device of the present disclosure, the flow rate changing section may change to supply a negative pressure of a large flow rate from the first flow path and the second flow path in a case where the size of the suction port is the predetermined size or more. With this, even in a case where the flow path is divided into two flow paths in order to appropriately detect whether the component is picked up, a negative pressure of a large flow rate can quickly reach the necessary negative pressure.

### INDUSTRIAL APPLICABILITY

The present disclosure can be used for a manufacturing industry of component mounting devices, and the like.

### REFERENCE SIGNS LIST

10: component mounting device, 12: base, 20: component supply device, 22: reel, 30: substrate conveying device, 32: conveyor belt, 40: moving device, 42, 46: guide rail, 44: X-axis slider, 45: X-axis actuator, 48: Y-axis slider, 49: Y-axis actuator, 50: head unit, 50a: head main body, 51: nozzle holding section, 51a: center hole, 51b: recessed portion, 51c: communication hole, 52: nozzle, 52L: large-diameter nozzle, 52S: small-diameter nozzle, 52a: suction port, 52b: flange portion, 54: R-axis actuator, 56: Z-axis actuator, 57: Z-axis slider, 62: part camera, 64: mark camera, 66: nozzle stocker, 70: pressure supply device, 71A: negative pressure source, 71B: positive pressure source, 72: negative pressure flow path, 73: positive pressure flow path, 74: large flow rate flow path, 74a, 78a: pressure sensor, 75: small flow rate flow path, 76: connection flow path, 77: ejector flow path, 78: nozzle holding flow path, 79: reduced pressure flow path, 81 to 87: switching valve, 88: ejector, 89: pressure reducing valve, 90: control device, 91: CPU, 92: ROM, 93: HDD, 94: RAM, 95: input/output interface, 96: bus, S: substrate

1. A component mounting device to which multiple types of nozzles having different sizes of suction ports each configured to pick up a component are detachably attached, the component mounting device comprising:
a nozzle flow path configured to supply a negative pressure from a negative pressure source to the suction port of the nozzle;
a pressure sensor configured to detect a pressure in the nozzle flow path;
a determining section configured to determine whether the component is picked up based on a detected value of the pressure sensor; and
a flow rate changing section configured to change a flow rate of the negative pressure supplied from the nozzle flow path to the suction port in accordance with a size of the suction port.

2. The component mounting device according to claim 1,
wherein the nozzle flow path comprises a first flow path and a second flow path having a smaller flow path diameter than the first flow path, and
the flow rate changing section changes to supply a negative pressure of a large flow rate from at least the first flow path in a case where the size of the suction port is a predetermined size or more, and changes to shut off supply of a negative pressure from the first flow path and to supply a negative pressure of a small flow rate from the second flow path in a case where the size of the suction port is less than the predetermined size.

3. The component mounting device according to claim 2,
wherein the flow rate changing section changes to supply a negative pressure of a large flow rate from the first flow path and the second flow path in a case where the size of the suction port is the predetermined size or more.
